(19) United States
(12) Patent Application Publication
(10) Pub. No.: US 2025/0034036 A1
(43) Pub. Date: Jan. 30, 2025

(54) METHOD FOR INCREASING THE EFFICIENCY OF A SOLAR MODULE OR A SOLAR COLLECTOR

(71) Applicant: GELITA AG, Eberbach (DE)

(72) Inventors: Michael VAN ELSACKER, Eberbach (DE); Tonja LIPP, Princeton, NJ (US); Stephan HAUSMANNS, Mannheim (DE); Nina RITTEREISER, Waldbrunn-Oberdielbach (DE); Matthias REIHMANN, Hemsbach (DE); Berthold KÕHLER, Neckargemünd (DE)

(21) Appl. No.: 18/911,469

(22) Filed: Oct. 10, 2024

Related U.S. Application Data
(63) Continuation of application No. PCT/EP2023/051815, filed on Jan. 25, 2023.

(30) Foreign Application Priority Data
Apr. 14, 2022 (DE) 102022109298.4

(51) Int. Cl. C03C 17/32

(52) U.S. Cl. CPC C03C 17/32

(57) ABSTRACT

The present invention relates to a method for increasing the efficiency of a solar module or a solar collector, wherein the solar module or the solar collector comprises a glass pane on the side that faces toward the sun. The method comprises the steps of applying an aqueous solution of collagen hydrolysate to the glass pane and allowing the aqueous solution to dry.

### CROSS-REFERENCE TO RELATED APPLICATIONS

This patent application is a continuation of International Patent Application No. PCT/EP2023/051815, filed Jan. 25, 2023, which claims priority to German Patent Application No. 10 2022 109 298.4, filed Apr. 14, 2022, each of which is hereby incorporated by reference in its entirety.

### FIELD OF THE INVENTION

The present invention relates to a method for increasing the efficiency of a solar module or a solar collector, wherein the solar module or the solar collector comprises a glass pane on the side that faces toward the sun.

### BACKGROUND OF THE INVENTION

In addition to wind power, the use of photovoltaic installations provides a significant contribution to the generation of electrical energy from renewable energy sources. In the worldwide effort to reduce energy production from fossil fuels as much as possible, the use of photovoltaic installations will become increasingly important. This applies in particular to large photovoltaic installations in regions such as, e.g., the desert regions of North Africa, in which a particularly high yield of solar radiation is possible due to the climatic conditions.

The solar modules used in a photovoltaic installation (photovoltaic modules) almost always have a structure in which the photovoltaically active solar cells are arranged under a glass pane for protection. This glass pane on the side of the solar module that faces toward the sun is permeable to the spectral component of sunlight that is usable by the solar cells, which is typically within a range of about 300 nm to about 1,100 nm.

Accumulations of dirt on the surface of the glass pane, which inevitably occur after a certain period of operation of a photovoltaic installation, result in a reduction of the efficiency of the solar modules. To counteract this, a cleaning of the solar modules at certain time intervals is necessary, depending on the environmental conditions and the resulting degree of contamination. Especially in the case of large photovoltaic installations in regions with a high solar yield, i.e. in particular in desert regions, the cleaning of the solar modules requires not only a large amount of effort, but due to the consumption of water is also problematic with regard to the conservation of resources. The accumulation of dust on the solar modules can reduce their efficiency within a month by up to 30%. On the other hand, cleaning off the dust with water can cause a significant portion of the operating costs, the economic profitability thereby sinking.

The described problem of the contamination of the glass pane for solar modules also relates in a corresponding manner to sun collectors (solar collectors), which are used in solar thermal installations for generating thermal energy from sunlight (in particular for hot water or heating support). Solar collectors of that kind also comprise a glass pane as a covering on the side that faces toward the sun.

### BRIEF SUMMARY OF THE INVENTION

In view of the problem described above, the object underlying the invention is therefore to provide a possibility to increase the efficiency of a solar module or a solar collector.

This object is achieved, in accordance with the invention, in the method of the kind stated at the outset by the steps:
applying an aqueous solution of collagen hydrolysate to the glass pane; and
allowing the aqueous solution to dry.

### BRIEF DESCRIPTION OF THE SEVERAL VIEWS OF THE DRAWINGS

FIG. 1 shows transmission spectra of quartz cuvettes after multiple applications and drying of an aqueous solution of collagen hydrolysate;

FIG. 2A shows a photographic depiction of specimen slides after applying test contamination and cleaning with water;

FIG. 2B shows a photographic depiction of specimen slides after pretreating with collagen hydrolysate solution, applying test contamination, and cleaning with collagen hydrolysate solution;

FIG. 3A shows a photographic depiction of specimen slides after pretreating with glass cleaner, applying test contamination, and cleaning with water; and

FIG. 3B shows a photographic depiction of specimen slides after pretreating with glass cleaner with collagen hydrolysate, applying test contamination, and cleaning with water.

### DETAILED DESCRIPTION OF THE INVENTION

By means of the method in accordance with the invention, a protective layer of collagen hydrolysate is formed on the surface of the glass pane. It has been determined that this protective layer reduces the accumulation of dirt particles on the surface and facilitates the removal of the dirt particles upon subsequent cleanings. As a result, the method in accordance with the invention thus causes an increase in the efficiency of the solar module or solar collector due to a lesser degree of contamination. On the other hand, the application of the method in accordance with the invention reduces the cleaning effort required to achieve a certain efficiency of the solar module or solar collector.

The method in accordance with the invention can be used particularly advantageously in the case of completely or partially transparent solar modules. In particular, these are solar modules in which the photovoltaically active solar cells are integrated into the glass pane. Such transparent solar modules have a potentially large application area as window glazings in buildings.

Collagen hydrolysate that is used in the context of the invention is created during chemical or enzymatic hydrolysis of the animal structural protein collagen, either through direct hydrolysis of the collagen or via the intermediate step of gelatin. Unlike gelatin, which forms a hydrogel at room temperature, due to its lower molecular weight collagen hydrolysate has no ability to form a gel, but instead is water-soluble at room temperature.

Surprisingly, the protective layer applied by means of the method in accordance with the invention causes no degradation of the efficiency of the solar module due to light absorption of the collagen hydrolysate in the photovoltaically useable wavelength range of sunlight. This is not self-evident, insofar as there is a known photoprotective effect for coatings on the basis of gelatin, e.g. in the protection of print colors from fading (cf. Berthold Köhler: “Light Stability of Gelatine Coatings”, Proceedings of International Congress of Imaging Science 2002, Tokyo, pages 369-370). Because the peptides of the collagen hydrolysate naturally have the same amino acid composition as the polypeptides of the gelatin, there is assumed to be comparable absorption characteristics. Here, in particular the aromatic amino acids tyrosine, phenylalanine, and histidine are relevant for absorption.

The application of the aqueous solution of collagen hydrolysate to the glass pane may take place with any suitable method of application, wherein a distribution that is as uniform as possible over the entire area of the glass pane is desirable. Preferably, the aqueous solution is spread on (e.g. by means of an absorbent applicator), sprayed on (with or without pressure), or poured on. The preferred application method can also be selected in consideration of the size and arrangement (e.g. horizontal or inclined) of the solar module or solar collector.

The amount applied per unit of area should be sufficiently large in order to enable a uniform distribution of the aqueous solution on the glass pane and, on the other hand, small enough so that not too much excess solution runs off the glass pane.

The aqueous solution favorably comprises a proportion of collagen hydrolysate of about 0.5% by weight or more, preferably about 0.7% by weight or more, further preferably about 0.9% by weight or more. It has been shown that a significant effect can already be achieved with this concentration of collagen hydrolysate.

The aqueous solution favorably comprises a proportion of collagen hydrolysate of up to about 10% by weight, preferably up to about 5% by weight, further preferably up to about 2.5% by weight.

For example, an aqueous solution with a proportion of collagen hydrolysate of 1 to 2% by weight is particularly preferable.

As already mentioned above, the collagen hydrolysate used in the method in accordance with the invention is, in particular, produced by chemical or enzymatic hydrolysis of collagen-containing animal starting materials. The animal starting material is preferably selected from skin or bone of vertebrates, in particular of cattle, swine, or sheep. The production of the collagen hydrolysate by enzymatic hydrolysis of gelatin, in particular using one or more endopeptidases, is particularly preferable.

Collagen hydrolysate is typically present as a mixture of peptides with a certain molecular weight distribution, wherein this molecular weight distribution can be influenced by the respective hydrolysis conditions (in particular by the enzymes used, hydrolysis duration, temperature, and pH value). The collagen hydrolysate typically has an average molecular weight of about 500 to about 25,000 Da, preferably about 1,000 to about 12,000 Da, further preferably about 2,000 to about 6,000 Da. These specifications always refer to the weight average molecular weight, which is determined by means of gel permeation chromatography.

Optionally, the aqueous solution that is applied to the glass surface may comprise further components in addition to the collagen hydrolysate. In accordance with an advantageous embodiment of the invention, the aqueous solution further comprises one or more surfactants, preferably in a proportion of about 0.5 to about 2.0% by weight. Such a solution can then simultaneously be used to clean the solar module or solar collector. In particular, the aqueous solution may be formulated as a conventional cleaning agent for glass surfaces, which additionally comprises collagen hydrolysate.

The surfactant(s) is/are preferably selected from non-ionic, anionic, and amphoteric surfactants. In addition to the surfactants, the aqueous solution may then also comprise further cleaning-active components such as, e.g., complexing agents, and/or additives such as, e.g., pH regulators and preservatives.

After the application of the aqueous solution of collagen hydrolysate, it is allowed to dry in order to form the protective layer of collagen hydrolysate on the glass pane. The drying of the aqueous solution hereby typically takes place within a few minutes, in particular by solar radiation.

In accordance with a preferred embodiment, the method in accordance with the invention comprises the repeated application and drying of the aqueous solution of collagen hydrolysate on the glass pane. Preferably, the application and drying of the aqueous solution takes place at time intervals of several days to several weeks, depending of the respective conditions, in particular the contamination levels of the solar modules or solar collectors.

Favorably, the glass pane is cleaned before each application of the aqueous solution of collagen hydrolysate. Between the cleaning cycles, the accumulation of dirt particles on the glass pane is reduced by the protective layer of collagen hydrolysate, such that the cleaning has to be performed less frequently and/or with lesser intensity in order to achieve an at least constant efficiency of the solar module or solar collector than would be the case without the application of the method in accordance with the invention.

In accordance with a further aspect, the invention also relates to the use of collagen hydrolysate for increasing the efficiency of a solar module or a solar collector, wherein the collagen hydrolysate is applied in the form of an aqueous solution to a side of the sole module or solar collector that faces toward the sun and the aqueous solution is then allowed to dry.

Advantages and preferred embodiments of the use in accordance with the invention were already discussed in connection with the method in accordance with the invention.

The following examples serve to further describe the invention without limiting it in any way.

### Example 1

### Change in the Transmission of Glass by Collagen Hydrolysate.

The following preliminary experiment was performed to show that with the method in accordance with the invention a collagen hydrolysate layer can be created on a glass surface and to determine the effect of this collagen hydrolysate layer on the transmission in the wavelength range of 190 to 800 nm:

Three cuvettes of quartz glass were filled with an aqueous solution that contained 1% by weight of a collagen hydrolysate with an average molecular weight of about 3,000 Da. This collagen hydrolysate is sold by the applicant GELITA AG as a 50% solution under the name NOVOTEC® CB800. After one minute, the solution was removed from the cuvettes and was allowed to dry for about 24 hours at room temperature.

After drying, the transmission of the three test cuvettes, as well as of an empty, untreated cuvette as a reference, was measured in the wavelength range of 190 to 800 nm using a UV/VIS photometer. The same procedure was then repeated three times (i.e. filling the cuvettes with collagen hydrolysate solution, emptying the cuvettes after one minute, measuring the transmission after a drying time of about 24 hours).

In order to also test the removal of the collagen hydrolysate layer by washing with water, the three test cuvettes were filled with demineralized water, said water removed after one minute, and the cuvettes again allowed to dry for about 24 hours. The transmission was then measured as described above, and the entire procedure was repeated three times.

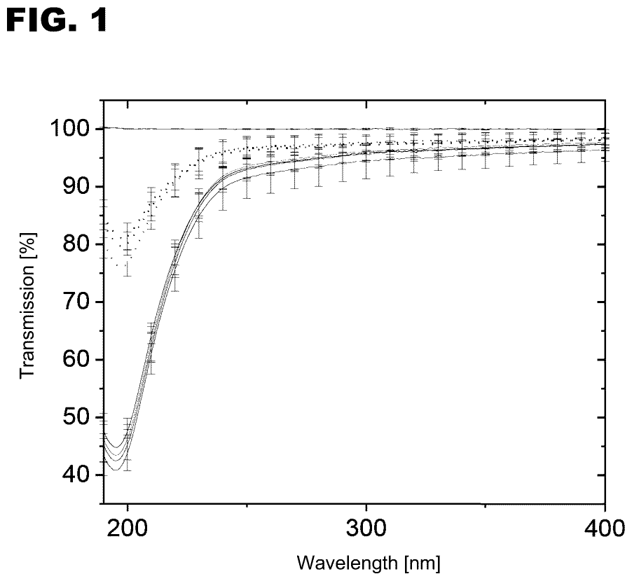

Depicted in FIG. 1 are the measured transmission spectra of the three test cuvettes (average and standard deviation) after the respective treatment steps in the wavelength range of 190 to 400 nm. The solid lines are the spectra after the four treatment steps with collagen hydrolysate solution, and the dotted lines are the spectra after the four washing steps with demineralized water. The transmission of the reference cuvette is 100% in the entire wavelength range.

The evaluation of the spectra shows, for one, that a collagen hydrolysate layer already formed on the surface of the quartz glass cuvettes after the first treatment step, said collagen hydrolysate layer having an absorption maximum in the range between 190 and 200 nm. Because the spectra after the four treatment steps are substantially identical, clearly no further buildup of the collagen hydrolysate layer occurs through additional treatments, but instead a sort of saturation of the surface takes place already after the first treatment with an aqueous solution of collagen hydrolysate.

The spectra of the test cuvettes after the four cleaning steps are also very close to one another. The higher transmission in comparison to the treated test cuvettes shows that the collagen hydrolysate layer is already partially removed by the first cleaning step, but about one third remains. This residual portion of the collagen hydrolysate layer is also changed only to an insignificant extent by the subsequent three washing steps.

The results show, on the one hand, that the collagen hydrolysate layer has no significant influence on the transmission of the glass in the spectral range useable by the solar cells above about 300 nm. The transmission of the treated cuvettes is about 95% or more in this range. In the wavelength range from 400 to 800 nm, which is not depicted in FIG. 1, all spectra continue to approach the value of 100%.

### Example 2

Cleaning of Glass Panes after Pretreatment with Collagen Hydrolysate Solution in Comparison to Water.

In order to demonstrate the effect of the method in accordance with the invention in cleaning glass panes, the following tests were performed:

Specimen slides were used as glass panes. Five respective specimen slides were cleaned with detergent and tap water, rinsed with demineralized water, and dried at room temperature. The cleaned slides were tested for identical spectra in the wavelength range of 350 to 800 nm, wherein the transmission was continuously about 90% in the entire range.

The specimen slides were dipped in an aqueous solution with 1% by weight of collagen hydrolysate (samples in accordance with the invention) or in demineralized water (comparison samples) and then stored therein at room temperature for five minutes. The same collagen hydrolysate was used as in Example 1 (NOVOTEC® CB800). After removal, the specimen slides were dried at room temperature.

The pretreated specimen slides were dipped in a test contamination solution and then stored therein for five minutes. For this purpose, a standard contamination solution according to the lime soap removal test of the German Cosmetic, Toiletry, Perfumery and Detergent Association (IKW) was used. After removal, the specimen slides were dried at room temperature and then stored at 50° C. for three hours in order to simulate an aging of the contamination.

After cooling, the specimen slides were dipped in an aqueous solution with 1% by weight of collagen hydrolysate (samples in accordance with the invention) or in demineralized water (comparison samples) and then dried at room temperature.

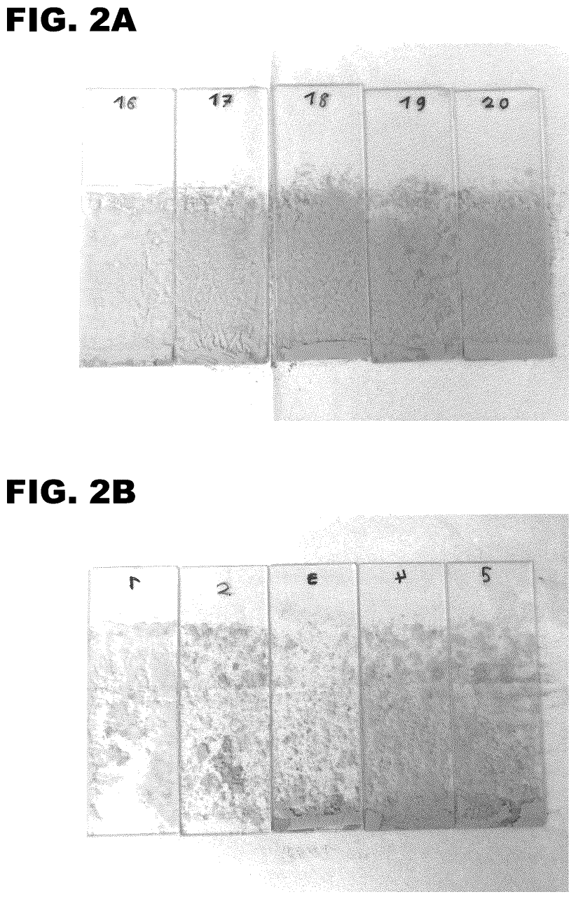

FIG. 2A shows a photographic depiction of the five specimen slides of the comparison samples, and FIG. 2B shows a photographic depiction of the five specimen slides of the samples in accordance with the invention.

In direct comparison, there is a significant difference between the comparison samples, in which nearly no cleaning of the test contamination has taken place, and the samples in accordance with the invention, in which significant portions of the contamination was able to be cleaned off. This result was able to be quantified with a photometer: All five specimen slides of the comparison samples showed no transmission (0%) in the range of 350 to 800 nm, while the transmission in case of the specimen slides of the samples in accordance with the invention was between about 10% and about 50%.

These results clearly show that a treatment of glass panes with collagen hydrolysate according to the method in accordance with the invention significantly contributes to reducing a contamination of the glass panes and to facilitating the cleaning of contaminations.

### Example 3

Cleaning of Glass Panes after Pretreatment with Glass Cleaner Plus Collagen Hydrolysate in Comparison to Glass Cleaner without Additive.

The tests described in Example 2 were repeated with the following changes:

In the case of the five specimen slides of the test samples, the pretreatment took place with a glass cleaner (Glass Window Cleaner, TER Group), with 1% by weight of a non-ionic surfactant as a main component, and the cleaning took place with demineralized water.

In the case of the five specimen slides of the samples in accordance with the invention, the pretreatment took place with the aforementioned glass cleaning with the addition of 1% by weight of the collagen hydrolysate (NOVOTEC® CB800), and the cleaning took place with demineralized water.

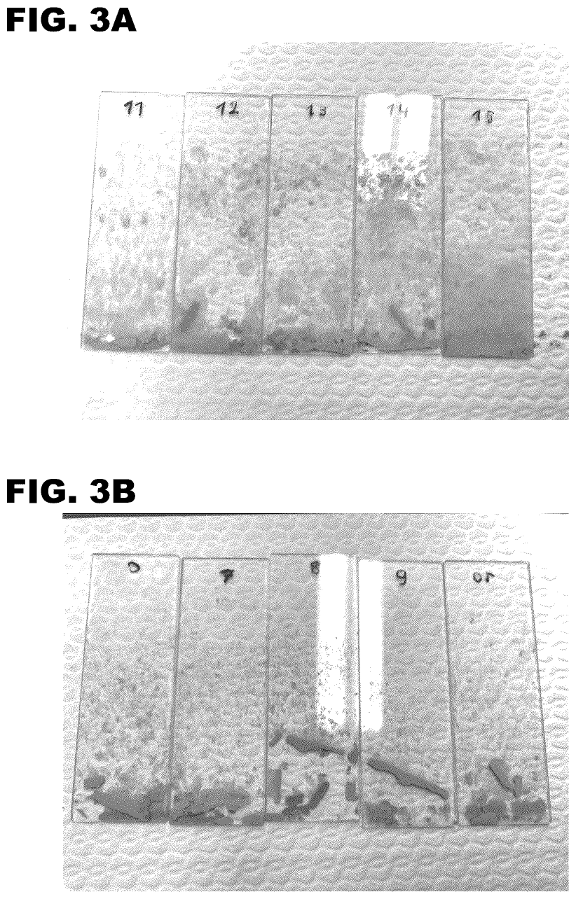

FIG. 3A shows a photographic depiction of the five specimen slides of the comparison samples, and FIG. 3B shows a photographic depiction of the five specimen slides of the samples in accordance with the invention.

In this case too, a direct comparison between the respective specimen slides shows that the pretreatment with collagen hydrolysate (as an additive to a glass cleaner) has a positive effect on the cleaning of glass panes. Even though a significant cleaning can be seen in the case of the comparison samples (though highly varying among the individual samples), the cleaning is uniform and significantly better in the case of the samples in accordance with the invention.

The measurement with the photometer resulted in a highly fluctuating transmission between about 20% and about 70% in the case of the individual specimen slides of the comparison samples. With the samples in accordance with the invention, the transmission was between 40% and 50% in four cases and about 65% in one case.

1. A method for increasing the efficiency of a solar module or a solar collector, wherein the solar module or the solar collector comprises a glass pane on the side that faces toward sun, comprising the steps:
applying an aqueous solution of collagen hydrolysate to the glass pane; and
allowing the aqueous solution to dry.

2. The method in accordance with claim 1, wherein the solar module is completely or partially transparent, and wherein the solar module comprises solar cells, which are integrated into the glass pane.

3. The method in accordance with claim 1, wherein the aqueous solution is spread, sprayed, or poured onto the glass pane.

4. The method in accordance with claim 1, wherein the aqueous solution comprises a proportion of collagen hydrolysate of about 0.5% by weight or more.

5. The method in accordance with claim 1, wherein the aqueous solution comprises a proportion of collagen hydrolysate of up to 10% by weight.

6. The method in accordance with claim 1, wherein the collagen hydrolysate is produced by chemical or enzymatic hydrolysis of collagen-containing starting materials.

7. The method in accordance with claim 1, wherein the collagen hydrolysate has an average molecular weight of about 500 to about 25,000 Da.

8. The method in accordance with claim 1, wherein the aqueous solution further comprises one or more surfactants.

9. The method in accordance with claim 8, wherein the surfactant(s) is/are selected from non-ionic, anionic, and amphoteric surfactants.

10. The method in accordance with claim 8, wherein the aqueous solution further comprises one or more components that are selected from complexing agents, pH regulators, and preservatives.

11. The method in accordance with claim 1, wherein the method comprises the repeated application and drying of the aqueous solution of collagen hydrolysate on the glass pane.

12. The method in accordance with claim 11, wherein the glass pane is cleaned before each application of the aqueous solution of collagen hydrolysate.

13. (canceled)
